(19) United States
(12) Patent Application Publication
(10) Pub. No.: US 2011/0048501 A1
(43) Pub. Date: Mar. 3, 2011

(54) SOLAR CELL MODULE

(76) Inventors: Joachim Jaus, Freiburg (DE); Andreas Bett, Freiburg (DE)

(21) Appl. No.: 12/937,842

(22) PCT Filed: Apr. 9, 2009
(86) PCT No.: PCT/EP09/02653

§ 371 Date: Nov. 22, 2010

(30) Foreign Application Priority Data
Apr. 15, 2008 (EP) 08007395.0

(51) Int. Cl. H01L 31/052; H01L 31/042

(52) U.S. Cl. 136/246; 136/244

(57) ABSTRACT

The invention relates to a solar cell module comprising at least two assemblies (SCA) which are connected to each other and have solar cells and also a module base plate comprising an electrically conductive carrier structure and a rear-side plate which is electrically insulated at least on the side orientated towards the carrier structure. The assembly comprising the solar cell is thereby particularly small with respect to dimensioning, which leads to low material consumption of heat sink material, e.g. copper and aluminium, and hence enables particularly economical production.

### CROSS REFERENCE TO RELATED APPLICATIONS

This application claims priority to international application no. PCT/EP2009/002653 filed on Apr. 9, 2009, which claims priority to European application no. 08007395.0 filed on Apr. 15, 2008, each of which is incorporated herein in its entirety.

### TECHNICAL FIELD

The invention relates to a solar cell module comprising at least two assemblies (SCA) which are connected to each other and have solar cells and also a module base plate comprising an electrically conductive carrier structure and a rear-side plate which is electrically insulated at least on the side orientated towards the carrier structure. The assembly comprising the solar cell is thereby particularly small with respect to dimensioning, which leads to low material consumption of heat sink material, e.g. copper and aluminium, and hence enables particularly economical production.

### BACKGROUND

For direct generation of electrical energy from sunlight, nowadays photovoltaic modules are already widespread. A technology in this field which is particularly promising for the near future is concentrator photovoltaics in which the solar energy is concentrated by means of an optical system and subsequently is converted into electrical energy by particularly high-performance solar cells (see e.g. A. W. Bett, F. Dimroth, S. W. Glunz et al., “FLATCON™ and FLASHCON™ Concepts for High Concentration PV”, Proc. of 19^{th} European Photovoltaic Solar Energy Conference, 2004, pp. 2488-2491).

A focal point with relatively high radiation density is produced by the concentration of sunlight. This radiation energy is converted in the solar cell into electrical energy up to a specific degree. This proportion is determined by the efficiency of the solar cell which has increased meteorically in the last few years and today has exceeded 40%, R. R. King, D. C. Law, K. M. Edmondson et al., “40% efficient metamorphic GaInP/GaInAs/Ge multijunction solar cells”, Applied Physics Letters, 90, 2007, pp. 1835161-1835163).

The part of the radiation energy which is not converted into electrical energy accumulates as thermal lost energy. Because of the high radiation density, particularly high requirements on the thermal design of a concentrator module consequently result. Since the efficiency and lifespan of a solar cell drop with higher temperature, it is the aim of every development in this field to keep the temperature of the solar cell as low as possible by suitable measures.

The high flux density of the heat energy in the concentrator photovoltaic system requires connection of the solar cells to an actively or passively cooled heat sink. In order to keep the costs for such a concentrator module particularly low, in particular a suitable combination of materials and also a design suitable for mass production predominates here. In addition to dissipation of the heat, the individual solar cells must be connected to each other electrically in a concentrator solar module. In order to keep the resistance losses which increase quadratically with the current strength as low as possible, usually a series connection of all the solar cells or even of a plurality of solar cell groups connected in parallel is implemented.

The heat sinks have to date generally been designed as a single component and correspondingly dimensioned, so-called SCA, Solar Cell Assembly. The individual solar cells are already contacted also on this cooling element and contact regions are made available for further connection at module level. A typical solar cell assembly according to the state of the art (documented e.g. in J. Jaus, U. Fleischfresser, G. Peharz et al., “Heat Sink Substrates for Automated Assembly of Concentrator Modules”, Proc. of 21^{st} European Photovoltaic Solar Energy Conference, 2006, pp. 2120-2123 or A. W. Bett, C. Baur, F. Dimroth et al., “FLATCON™ modules: Technology and Characterisation”, Proc. of 3^{rd} World Conference on Photovoltaic Energy Conversion, 2003, pp. 634-637 or U.S. Pat. No. 5,167,724) consists of a solar cell, a substrate for heat conduction (e.g. copper), a plurality of applied metal layers for improving the contactability, a solder or adhesive layer for contacting the solar cell rear-side and also bonded or welded contactings of the solar cell upper side.

The two terminals of the solar cell respectively are connected electrically to one of the metal layers. For this purpose, the rear-side contact, of a planar design, of the solar cell is connected in a planar manner to a first metal layer. The front-side contact of the solar cell is connected to a second metal layer. Since also the active surface of the cell is situated on the front-side of the solar cell next to the front-side contact, the front-side contact is preferably designed to be very small in comparison to the active surface in order to be able to use as much as possible of the radiated sunlight for current generation. The connection to the front-side contact is therefore generally implemented by a very thin bonding wire (approx. 50 μm). In addition to the electrical connection, the SCA assumes the task of dissipation of the accumulated lost heat. This function of a heat sink firstly comprises the transmission of heat energy from the cell to the various metal layers of the SCA (in particular via the planar rear-side contact to the metal layers connected thereto) and also the transmission of the heat to the module rear-side. On the other hand, “heat spreading” is necessary, i.e. the distribution of heat over a larger area. This is necessary in particular with highly concentrating systems in which a relatively high radiation density and hence also heat density is achieved. Individual solar cell assemblies are mounted in the state of the art on a module base plate. This module base plate dissipates the heat energy to the environment. The individual SCAs are mounted on this module base plate such that the solar cell is situated as exactly as possible at the focal point of the lens plate mounted thereabove (or of another optical system for concentration of solar radiation). After mounting the SCAs on the base plate, the electrical wiring of the SCAs to each other takes place. According to the desired module voltage, series connection and parallel connection can be combined with each other. The base plate must be designed for this purpose to be insulating since otherwise even the mounting of the SCAs would lead to a parallel connection of all the SCAs of one module, which would lead to the generation of particularly high currents and is undesired because of the ohmic losses occurring as a result.

With respect to the production of module base plates using solar cell assemblies according to the state of the art, the following disadvantages should be mentioned:

The solar cell assemblies require a relatively large area for spreading the heat accumulating in the solar cell. Copper is the most frequently used base material for this task because of its good heat conductivity. Very high material costs occur as a result due to the high price of copper.

The rear-side of the solar cell cannot be glued or soldered directly onto copper. For this purpose, also further metallic layers are required. Nickel as a diffusion barrier followed by a thin gold layer is a common combination. The galvanic process step required for this purpose incurs high material and process costs due to the large planar extension. Due to the use of masks, in fact these contact metals can be applied only at the points at which they are also required, however the entire surface area of the SCAs must nevertheless be guided through the galvanic plant and thus the process costs increase.

In order to mount the solar cell on the heat sink and also in order to contact the solar cell front-side, plants from microelectronic production are used. These plants are designed specially for the purpose of contacting integrated circuits at high speed. Due to the relatively large surface area of the solar cell assemblies, in practice the throughput in these plants is noticeably reduced. The processing speed no longer influences the throughput on a corresponding plant, but rather the speed at which the SCAs can be moved in and out.

The base plate material, glass, which has been frequently used to date according to the state of the art is in fact very economical but has only a relatively low heat conduction coefficient (<2 W/mK). As a result, the base plate can assume a heat spreading function only very poorly, rather it can merely conduct the heat from an SCA with a large-area design to the external air.

Since the solar cell according to the state of the art as described above is mounted directly on the copper surface with the rear-side contact, the solar cell upper side must be contacted on a second, electrically insulated surface. For this purpose, the solar cell assembly itself must be designed by multilayer technology (J. Jaus, U. Fleischfresser, G. Peharz et al., “Heat Sink Substrates for Automated Assembly of Concentrator Modules”, Proc. of 21^{st} European Photovoltaic Solar Energy Conference, 2006, pp. 2120-2123 or it must have a contacting pad. Both incur additional material and process costs.

Furthermore, embodiments in which the base plate itself has a plurality of metal layers are known according to the prior art (U.S. Pat. No. 6,248,949 B1 and WO 91/20097). These metal layers respectively are connected directly to the solar cell front-side or rear-side. These base plates are generally designed by circuit board technology in which a plurality of conducting (e.g. Cu) and non-conducting (e.g. glass fibre-epoxy resin) metal layers are connected to each other by lamination. In order to produce a series connection, the layers are thereby structured by a photolithographic structuring process and thus regions which are insulated from each other electrically are produced and are connected then to each other via the solar cells.

With respect to the production of module base plates using multilayer technology according to the state of the art, the following disadvantages should be mentioned:

Metal layers of different thicknesses can be used as conduction layer, typically copper is used in thicknesses of 0.035 to 0.5 mm. Typically, at least one of the layers has a thicker design (>200 μm) in order to implement the heat spreading. However, not all solar cells can be placed directly on this heat-conducting layer since a parallel connection of all these cells would consequently take place, with the described negative consequences. The solar cell must therefore be mounted on an electrically conductive layer which need not however be insulated from this main heat-conducting layer. Generally, epoxy resin-saturated glass fibre fabrics are used as insulation material in the state of the art (e.g. FR4). Almost all commercially available circuit boards are based also on this material. Even if this layer can be designed to be very thin by a progressive multilayer technology (<100 μm), nevertheless a very high thermal resistance is produced, due to the low heat conduction coefficient of FR4 (<1 W/mK).

The influence of this high thermal resistance is assessed to be particularly great since the lost heat at this point has not yet been spread, i.e. a high heat flow takes place on a very small cross-sectional area. According to the heat conduction equation according to Fourier, these two factors lead to an undesired high cell temperature.

In order to produce a series connection, at least one conducting layer must be structured, i.e. separated into individual electrically insulated regions. For this purpose, photolithographic structuring methods are applied according to the state of the art. For this purpose, a photomask is exposed, developed and the copper is etched at the corresponding places. This process is relatively costly, in particular since it must be implemented over the entire surface of the module base plate.

### SUMMARY

Starting herefrom, it was the object of the present invention to provide solar cell modules which eliminate the described disadvantages of the state of the art and can be produced simply and economically.

This object is achieved by the solar cell module having the features of claim 1 and the concentrator solar cell module having the features of claim 19. The further dependent claims reveal advantageous developments.

According to the invention, a solar cell module is provided, which has at least two assemblies (SCAs) which are connected to each other and have solar cells and also a module base plate comprising an electrically conductive carrier structure and has a rear-side plate which is electrically insulated relative to the carrier structure. This carrier structure thereby has regions (SCA regions) which are separated from each other and fitted with solar cell assemblies and also has connection regions and a connection of the solar cell assemblies is effected by electrical contacting of the SCA regions with the front-side of an adjacent solar cell and also by electrical contacting of the SCA regions with respectively an adjacent connection region as series circuit or by SCA regions to each other and connection regions to each other as parallel circuit.

### BRIEF DESCRIPTION OF THE DRAWINGS

The subject according to the invention is intended to be explained in more detail with reference to the subsequent Figures without wishing to restrict said subject to the special embodiments shown here.

FIG. 1 shows a view (FIG. 1a), a perspective (FIG. 1b) and a section (FIG. 1c) of a solar cell assembly according to the invention with filling compound. The carrier structure here has the region 1 fitted with solar cell assemblies and a connection region 2, which are separated from each other spatially at least partially. On the SCA region 1, a solar cell 3 is coupled by means of a conductive adhesive or solder. Furthermore, a protective diode 6 is disposed on the SCA region 1 by means of a conductive adhesive or solder. Solar cell 3 and protective diode 6 are contacted with each other e.g. by thin wire bonds 7. In FIG. 1, this solar cell module is enclosed in a filling compound 9.

In FIG. 2, a view (FIG. 2a), a perspective (FIG. 2b) and a section (FIG. 2c) of the solar cell module according to the invention is represented. Of concern hereby is a variant without filling compound. The reference numbers correspond to those of FIG. 1, in addition in this drawing the contacting of the solar cell front-side by means of thin wire bonds 8 being able to be detected.

In FIG. 3, a connection of six solar cell assemblies according to the invention is represented by way of example.

FIG. 4 shows a chip carrier strip with SCA regions 1, connection regions 2 and also third regions which can have auxiliary elements such as a perforated mask for indexing the metal strip in the process plants.

FIG. 5 shows the arrangement of solar cell modules according to the invention. The rear-side plate 12, e.g. made of aluminium, has here an insulation layer 13, e.g. an anodised aluminium layer, on the surfaces. This rear-side plate is coupled by means of a connection material 14 to a second rear-side plate, e.g. by means of a varnished steel plate. This second rear-side plate can have further functional elements, e.g. reinforcing beads 11 and 11′. The SCA 17 is connected via a connection means 16 to the rear-side plate.

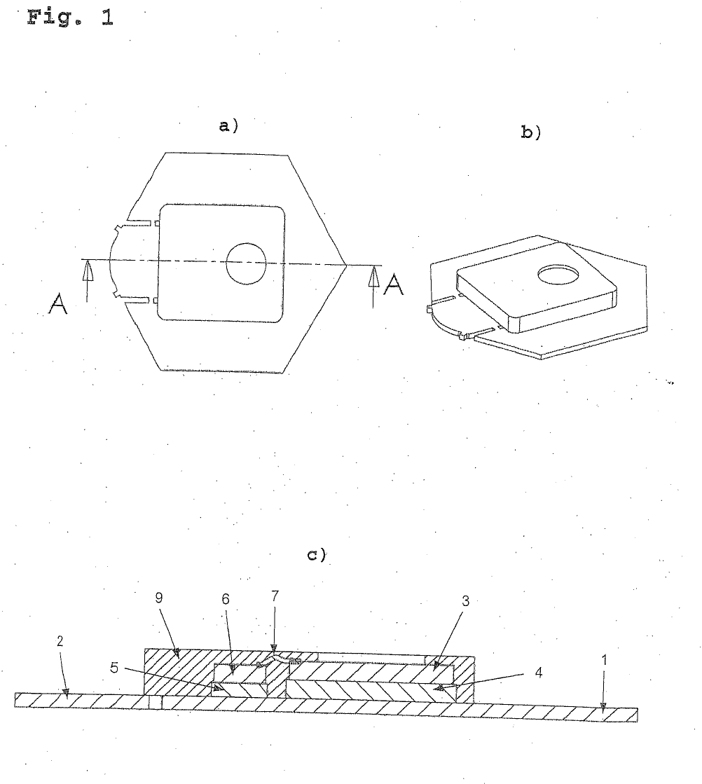

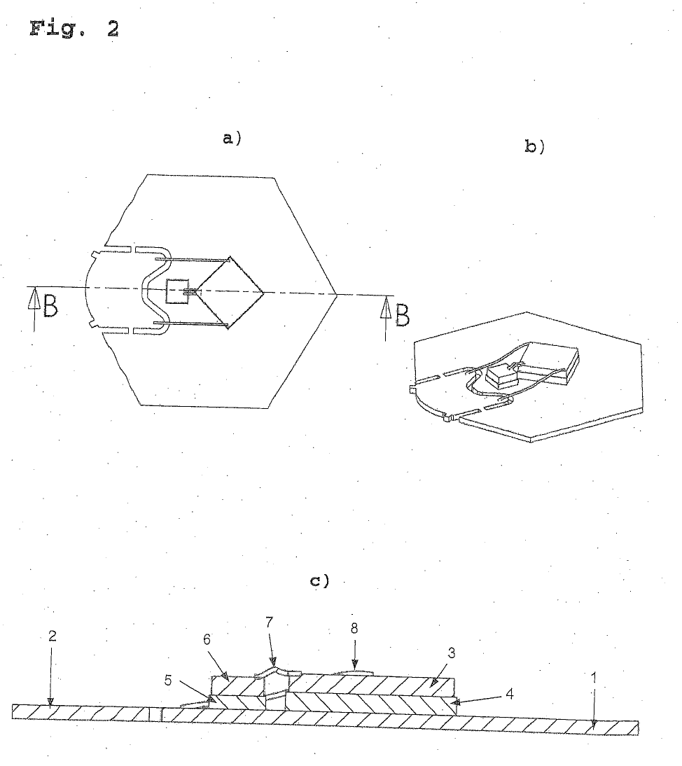

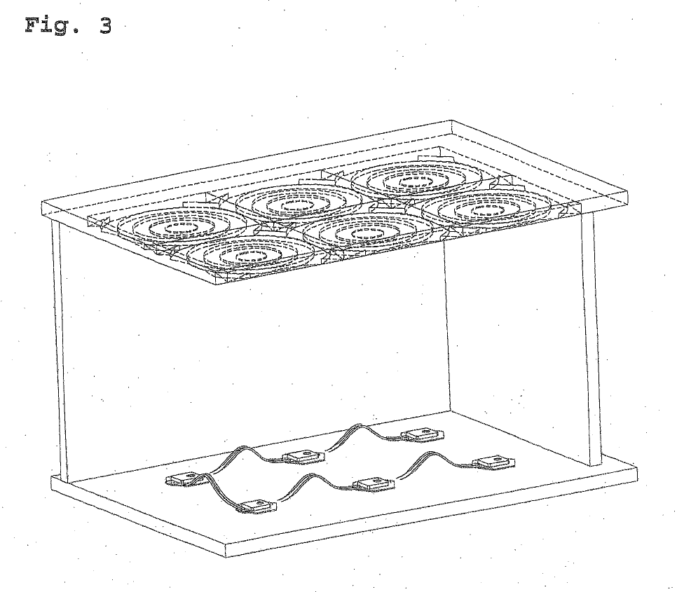

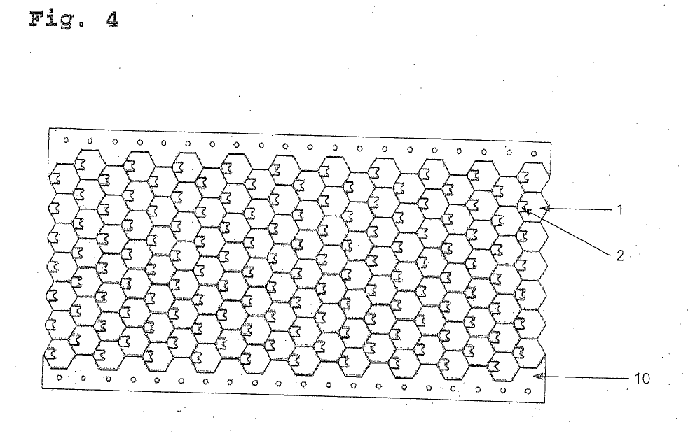

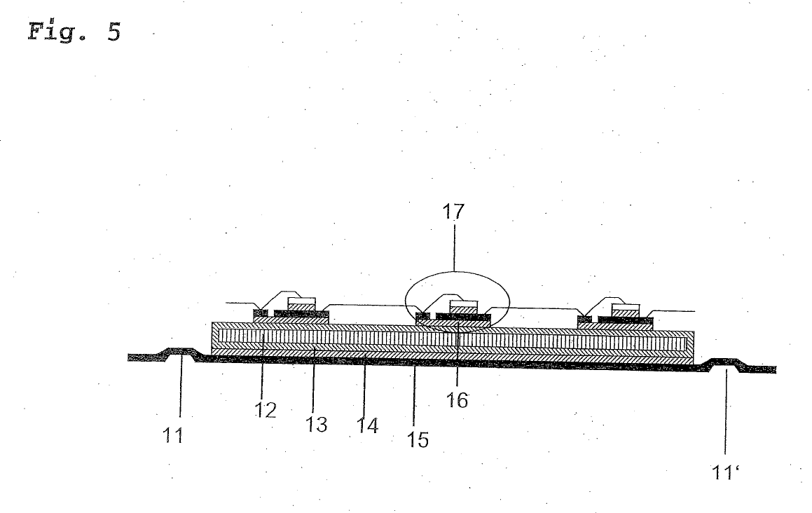

### DETAILED DESCRIPTION

In contrast to the state of the art in which the SCA assumes both the electrical contacting and the heat spreading, these functionalities are divided up according to the invention. The SCA assumes above all the electrical contacting of the solar cell and also a first heat spreading in the critical region of a few mm around the cell. As a result, the SCA can turn out to be significantly smaller. Thus the surface area of the carrier structure, because of the two-stage heat spreading, is generally less than half of the overall solar cell module surface, sometimes even only a quarter of the solar cell module surface. The actual heat spreading to as large a surface area as possible is assumed, according to the invention, by the rear-side plate which can be designed, because of its electrically insulated connection to the SCA, as for example a continuous foil and thus demands no structural complexity. Of concern therefore is a two-stage heat spreading in which firstly a first heat spreading is effected via the SCA region and subsequently a second heat spreading via the rear-side plate.

According to the invention, decoupling of the heat-spreading surface and electrical connection surface can be made possible by the described regions. The electrical connection functionality is hence jointly assumed according to the invention by the carrier structure.

Preferably, the carrier structure is of monolithic origin and the separation of the regions is effected by punching.

The carrier structure can be both a carrier strip or even a carrier plate. Preferably, it consists of a metallic strip material having a thickness in the range of 0.1 to 5 mm, in particular 0.2 to 0.5 mm. At the same time, the carrier structure should have high thermal and electrical conductivity. Copper with low alloy proportions of iron or nickel is particularly suitable for this purpose. This carrier structure is then structured e.g. by stamping of individual regions which are firstly all connected to each other via webs (so-called punched bridges). SCA regions on which the solar cell is subsequently mounted are thereby produced. Furthermore, connection regions which serve as connection platforms subsequently are formed. Optionally, it is also possible that third regions are produced which have auxiliary elements, such as a perforated mask for indexing the metal strip in the process plants.

In a preferred embodiment, in order to improve the electrical contactability, the carrier structure can be provided with further metallic layers over the entire surface or also only in regions at the required places. These metals can then serve for example as diffusion barriers, e.g. nickel, palladium or silver, or as oxidation barrier, e.g. gold.

Preferably, the solar cell is connected to the carrier structure in the SCA region with the help of an electrically conductive adhesive or by means of solder over the planar rear-side contact. The front-side contacts of the solar cell can be connected subsequently to a connection region of the carrier structure by electrical contacting, e.g. by thin wire bonding. Subsequently, the thus mounted and contacted solar cell can be encapsulated for example by means of an injection moulding process. At the same time, the SCA regions and the connection regions are connected to each other mechanically by this step. If this injection moulding step is omitted, then also a mechanical connection can be effected alternatively via a fixing strip or a glued or soldered auxiliary element.

Subsequently, punching of the SCA regions and connection regions which are now connected to each other in addition by the casting can be implemented by separating the punched bridges. The individual SCAs present after this step can be subjected now if necessary to an additional quality check, e.g. by measuring characteristic lines, and thus subsequently ready for mounting on the rear-side plate.

Another alternative provides that the connection regions, i.e. the connection platform, can be produced also on a separate carrier structure, e.g. a metal strip. In this case, the contacting of the solar cell upper side is firstly omitted. This then takes place only after mounting of the SCA regions and the connection regions on the rear-side plate.

The rear-side plate preferably consists of a metal sheet which conducts well thermally (k>50 W/mK), of the thickness 0.1 to 5 mm, particularly preferred 0.2 to 0.5 mm. Preferably, the rear-side plate consists of an aluminium alloy.

The SCAs are mounted on this aluminium plate provided with an anodised layer by means of thermally readily conductive adhesive with a heat conductivity in the range of 0.2 to 50 W/mK, particularly preferred >1.5 W/mK. The electrical connection to each other is effected by an electrical connection between the SCA regions and the connection regions. In order to achieve a series connection, elements of the SCA region are connected alternately to the connection region.

A module base plate configured in this manner is preferably connected via a frame construction to a lens plate to form a finished module. In addition to using a frame construction, it is possible here that the rear-side plate or the substrate plate used for the mechanical stabilisation is formed by reforming, e.g. deep drawing, in such a manner that it can jointly assume the functionality of the frame and the lens plate is then directly connected to this plate. If, in order to save material, particularly thin rear-side plates are used, then these can be applied on a substrate plate made of a mechanically stable material, e.g. steel, plastic materials, glass, glass fibre composite materials.

In the following, again preferred embodiments of the subject according to the invention are cited.

Production of the rear-side plate can consist in one element (e.g. an anodised aluminium plate of the thickness 2 mm) or also be achieved via a plurality of elements. There is possible here above all the production via a relatively thin metal foil, preferably made of aluminium with a thickness of approx. 100 to 300 μm, which can be provided economically with an insulation layer in the roll-to-roll process, e.g. by anodic aluminium anodisation, vapour-deposited oxide layer, plasma-assisted application processes of inorganic compounds, gluing/lamination of an insulating foil or painting by roller or spraying process.

This foil can then be clamped on a stable frame construction, e.g. consisting of a twice folded metal strip. Alternatively thereto, a self-supporting construction can be achieved by lamination on a mechanically stable carrier substrate, e.g. zinc-plated steel, glass, fibre composite materials, laminates or aluminium.

The base plate is advantageously produced as a self-supporting sheet metal construction. In this context, this means that the necessary mechanical stability is produced not, as is normal in the state of the art, exclusively by material thickness but by suitable shaping of the rear-side plate. This can be produced for example by the formation of beads, reinforcing folds, pleats.

If the module is intended to have a hermetically sealed design, then the module base plate advantageously has an effective modulus of elasticity which is 0.1 to 2 times, particularly preferably 0.2 to 0.8 times, that of the lens plate. This can be achieved for example by a suitable thickness and choice of material of the rear-side plate. As a result, the pressure reached at a specific module temperature in the interior of the module is reduced more greatly by the base plate than by the lens plate. The base plate then assumes the function of a pressure membrane. As a result, the deflection of the lens plate can be reduced and hence the so-called off-pointing, i.e. the running off of the focal point from the active cell surface, can be avoided.

In order to improve the membrane function, the module base plate has special regions for this purpose in the edge region of the module in which the elasticity is increased. This is achieved advantageously via a reduced material thickness or by special shaping, such as double foldings.

In order to dissipate the lost heat accumulating in the solar cell and also for distribution thereof to a larger surface area, a plurality of materials is used. These materials are thereby chosen such that the heat conduction coefficient k is highest for those materials which are used in the immediate vicinity of the solar cell. The use of thermally very readily conducting materials is hereby particularly important because of the still very high flux density. With increasing enlargement of the conduction cross-section, also the heat conductivity can then also drop without the result being an accumulation of heat. In comparison with the state of the art in which a single material/element is used as heat sink, a great reduction in the use of material or material costs can consequently be achieved.

The following material combination of a production of the base plate according to the invention may be mentioned here by way of example:
a. SCA regions of the carrier structure: copper alloy, heat conductivity ˜380 W/mK
b. Anodised aluminium plate: aluminium alloy, heat conductivity ˜210 W/mK
c. Zinc-plated steel carrier plate: alloyed steel, heat conductivity ˜40 W/mK

Between the solar cell and the elements for the heat dissipation or between the individual elements for heat dissipation, connection materials are used which are likewise selected according to the principle of “graded heat transfer coefficient”. As a result, the use of particularly readily conducting (and therefore generally also expensive) connection materials can be restricted to a minimum. The following gradation may be mentioned here by way of example:
a. Connection of cell to SCA regions of the carrier structure: silver-filled conductive adhesive with k˜5 W/mK
b. Connection of SCA regions of the carrier structure to the anodised aluminium plate: epoxy resin filled with aluminium hydroxide with k˜1.5 W/mK
c. Connection of anodised aluminium plate to mechanical carrier: unfilled epoxy resin with k˜0.2 W/mK

Analogously to the graded thermal conductivity, the materials for minimising stresses due to different thermal expansion are selected as far as possible according to a graded thermal expansion coefficient (CTE—coefficient of thermal expansion)
a. Silicon or germanium with a CTE of 2.6 ppm/° K or 5.8 ppm/° K are used as solar cell substrate
b. This substrate is mounted on a carrier structure made of copper, CTE of copper is 16.7 ppm/° K
c. The anodised aluminium plate has a CTE of 23 ppm/° K

In contrast to the state of the art in which two different layers which are insulated from each other electrically are used, both electrical regions, in the case of the subject of the invention, are produced on only one carrier structure (SCA regions and connection regions). Due to suitable casting technology/punching technology and also due to the use of an insulated rear-side plate, the desired series connection can be achieved consequently in a significantly simpler manner.

In the shaping of the SCA regions and the connection regions of the carrier structure, two objectives which affect each other mutually exist: in order to keep the bonding wire length as short as possible, the connection region should be introduced as close as possible to the SCA region. However, this impairs the radial heat dissipation from the cell since the SCA regions and connection region can no longer be connected to each other via the metal strip surface after the punching. Therefore, the connection region is advantageously configured as a tongue which protrudes slightly into the SCA region. As an optimum compromise between bonding wire length and limiting of the heat conduction, the minimum spacing relative to the cell surface should be between 1 and 10 mm (better between 2 and 5 mm).

The rear-side plate can have a double insulation. In order to achieve high system voltages (in current systems ˜800 V), good insulation must be ensured. In order to ensure the necessary safe insulation, the rear-side plate is provided with a double insulation:
a. 1. Insulation in the SCA direction (interior insulation layer)
b. 2. Insulation in the direction of exterior air or second rear-side plate (exterior insulation layer)

This double production of the insulation layers can be achieved very economically when using aluminium, by means of an anodisation process implemented on all sides, in which the aluminium is converted (electrically oxidised) in the regions close to the surface in an acidic electrolyte bath to form aluminium oxide.

Further insulation layers are possible in the SCA direction by means of an electrically non-conducting adhesive. This is advantageously implemented by applying a corresponding layer even before the separation. Directly after application, this layer is already partially pre-polymerised so that it is no longer tacky at room temperature. In the attaching process, this layer is then completely through-polymerised and forms a solid connection between carrier structure of the SCA and rear-side plate.

Further insulation possibilities exist in the direction of reinforcing substrate plates by means of a non-conducting adhesive and also on the module rear-side by an electrically insulating dipping varnish.

After the solar cell and the protective diode have been mounted on the SCA region (“die-attach”) and also the wire bonding process for the connection region is concluded, it is possible to encapsulate these semiconductor chips and also the wire bonding connections. As a result, protection of the contacts and also of the sensitive solar cell edges against moisture-caused corrosion is achieved. If a non-transparent encapsulation material is chosen, then the active region of the solar cell is left open. Both dispensing and injection moulding are considered as casting process.

In the case of suitable transparent (absorption <20% of 400-2000 μm wavelength) encapsulation materials, a so-called secondary lens system is advantageously formed directly above the cell during the injection moulding process and influences the beam path of the sunlight such that a higher average radiation flow can be achieved on the solar cell. This can be effected for example by the formation of a lens or of a funnel based on internal reflection. The non-transparent encapsulation advantageously has formations which serve to mount a reflective secondary lens system, e.g. tabs for a click-on assembly.

What is crucial for a low cell temperature is the achievement of an efficient heat output to the environment. The proportion of the heat radiation is thereby relatively large. The subject of the invention therefore advantageously has the following elements:
a. A layer with a high emission capacity in the range of 2,000-10,000 μm on the upper side of the rear-side plate. The use of anodised aluminium for this purpose is advantageous here since the anodised aluminium layer already automatically has a high emission capacity in this range. Due to a high infrared emission capacity of the upper side of the rear-side plate, the radiation towards the lens plate is increased. As a result, the lens plate expands more greatly, which should be judged as positive because of the likewise relatively high base plate expansion. In addition, the lens plate can radiate into space, as a result of which a higher net radiation transfer is produced than in the case of the module base plate which is in radiation exchange with the ground.
b. A layer of high emission capacity in the range of 2,000-10,000 μm on the underside of the base plate (e.g. varnish, foil). If aluminium is used as material on the rear-side, then the anodised layer is also advantageous here for this purpose.

In order to increase the infrared emission capacity present already partially in the basic materials, coatings and paint can also be used. Advantageously, thin layers made of SiO₂ can be mentioned here or also coats of oil paints.

The layers for connecting the solar cell to the SCA regions of the carrier structure are advantageously produced via a solder connection based on SnPb, SnAg, AnAgCu or via a conductive adhesive based on epoxy resins, silicones or thermoplastics with silver- or copper-based fillers.

The layer for connecting the solar cell assembly to the rear-side plate is advantageously produced from epoxy resin, acrylate, kapton, silicone adhesive or a thermoplastic with fillers aluminium oxide, aluminium hydroxide or boron oxide, aluminium nitride, boron nitride.

As an alternative hereto, a layer of non-conducting plastic material (also in the form of partially crosslinked epoxy resins or other partially cured adhesives) can also be used on the rear-side of the lead frame. This layer is present as film at room temperature and is firstly connected to the rear-side of the lead frame. As a result, the individual regions of the carrier structure are also held together during punching. After the punching, the SCAs can then be connected securely to the base plate by means of this layer. This layer can also assume the task of electrical insulation.

The electrical contacting of the solar cell assembly for internal module connection is advantageously produced via the following technologies:
a. Ultrasound thick wire with aluminium wires
b. Thermocompression bonding with Cu
c. Welding processes of Cu- or Al strips or wires
d. Contact by adhesion only

For contacting by adhesion only, a network comprising metallic strip conductors is applied on the insulation layer of the rear-side plate, e.g. by deep drawing, screen printing or inkjet processes.

This network of strip conductors can be increased in order to improve the current conduction by galvanic or currentless processes.

Advantageously, suitable elements for attachment (e.g. borings, threaded inserts), and also further connection elements, connector boxes, mounting elements are integrated in the base plate.

1. Solar cell module comprising:
a module base plate comprising a rear-side plate having an electrically insulated layer;
an electrically conductive carrier structure on the rear-side plate and electrically insulated from the rear-side plate with the electrically insulated layer, wherein the electrically conductive carrier structure includes at least two regions, each region including a solar cell assembly region and a connection region which are separated from each other; and
at least two solar cell assemblies each having a solar cell and each mounted to the solar cell assembly region of the electrically conductive carrier structure, wherein the solar cell assemblies are effected by electrical contacting of the solar cell assembly regions with a front-side of an adjacent solar cell and also by electrical contacting of the solar cell assembly regions with an adjacent connection region as a series circuit or by solar cell assembly regions to each other and connection regions to each other as a parallel circuit.

2. Solar cell module according to claim 1, wherein the electrically conductive carrier structure is of monolithic origin and the solar cell assembly region and the connection region are separated by punched areas.

3. Solar cell module according to claim 1, where the solar cells are connected to the electrically conductive carrier structure integrally by means of an adhesive or solder.

4. Solar cell module according to claim 1, wherein the electrically conductive carrier structure is a carrier strip or a carrier plate.

5. Solar cell module according to claim 1, wherein the electrically conductive carrier structure consists of a metal or a metal alloy having a heat conductivity >50 W/mK, the metal or metal alloy being one of copper, a copper-iron alloy or a copper-nickel alloy.

6. Solar cell module according to claim 1, wherein the electrically conductive carrier structure has a thickness in the range of 0.1 to 5 mm.

7. Solar cell module according to claim 1, wherein the electrically conductive carrier structure further comprises one or both of regions with a diffusion barrier of a metallic coating, made of nickel, palladium or silver, or regions with an oxidation barrier made of gold.

8. Solar cell module according to claim 1, wherein the rear-side plate has a thickness of 50 to 500 μm.

9. Solar cell module according to claim 1, wherein the rear-side plate consists of a metal or a metal alloy having a heat conductivity ≧50 W/mK.

10. Solar cell module according to claim 1, wherein a two-stage heat spreading is effected with a first heat spreading via the solar cell assembly region and a second heat spreading via the rear-side plate.

11. Solar cell module according to claim 1, wherein the electrically insulated layer is made of aluminium oxide and is disposed between the electrically conductive carrier structure and the rear-side plate.

12. Solar cell module according to claim 1, further comprising a substrate plate connected to the rear-side plate opposite the electrically conductive carrier structure, the substrate plate made of steel, plastic material, glass and/or glass fibre composite materials.

13. Solar cell module according to claim 1, wherein the electrical contactings are bond wires.

14. Solar cell module according to claim 1, further comprising an additional mechanical fixing for the carrier structure comprising one of an injection moulded encapsulation, a fixing strip and/or an integrally connected auxiliary element.

15. Solar cell module according to claim 1, further comprising at least one protective diode for conducting away electrical currents in a barrier direction of the solar cell, the protective diodes being disposed preferably on the solar cell assembly regions of the electrically conductive carrier structure.

16. Solar cell module according to claim 15, wherein the protective diodes respectively are contacted electrically on the front-side with an adjacent solar cell.

17. Solar cell module according to claim 1, further comprising an anti-corrosive layer.

18. Solar cell module according to claim 1, wherein the solar cells are monolithic multiple solar cells made of elements of periodic table group III and V.

19. Concentrator solar cell module comprising a solar cell module according to claim 1 and an optical device for concentrating solar energy.

20. Concentrator solar cell module according to claim 19, wherein the optical device is a single-stage or two-stage concentrator lens system.
